(19) United States
(12) Patent Application Publication
(10) Pub. No.: US 2026/0040996 A1
(43) Pub. Date: Feb. 5, 2026

(54) ELECTRONIC DEVICE

(71) Applicant: Advanced Semiconductor Engineering, Inc., Kaohsiung (TW)

(72) Inventors: Chih-Pin HUNG, Kaohsiung (TW); Chien Lin CHANG CHIEN, Kaohsiung (TW); Chiu-Wen LEE, Kaohsiung (TW); Jung Jui KANG, Kaohsiung (TW); Chang Chi LEE, Kaohsiung (TW)

(73) Assignee: Advanced Semiconductor Engineering, Inc., Kaohsiung (TW)

(21) Appl. No.: 18/789,618

(22) Filed: Jul. 30, 2024

(51) Int. Cl. H01L 25/065; H01L 23/00; H01L 23/48; H10B 80/00

(52) U.S. Cl. CPC H01L 25/0657; H01L 23/481; H01L 25/0652; H10B 80/00; H01L 24/13; H01L 24/16; H01L 24/32; H01L 24/73; H01L 2224/13105; H01L 2224/13109; H01L 2224/13111; H01L 2224/13113; H01L 2224/16148; H01L 2224/16227; H01L 2224/32137; H01L 2224/32145; H01L 2224/73204; H01L 2225/06513; H01L 2225/06517; H01L 2225/06541; H01L 2924/1436; H01L 2924/381

(57) ABSTRACT

An electronic device is provided. The electronic device includes an electronic device includes an electronic component, and an interposer. The interposer is coupled to the electronic component, which includes first signal transmission vias, power transmission structures, and a circuit within the interposer. The circuit includes an active component, a passive component, or both.

### BACKGROUND

### 1. Field of the Disclosure

The present disclosure relates to an electronic device, and particularly to an electronic device including an interposer.

### 2. Description of the Related Art

The interposer, configured to serve as a conductive path between electronic components and/or devices, has through vias designed to transmit a signal. In a conventional electronic device, power is transmitted by pillars outside the interposer. In such structure, the bonding between the electronic component, interposer, and pillars is difficult because a relatively large pitch mismatch among these elements. Therefore, a new electronic device is required.

### SUMMARY

In some embodiments, an electronic device includes an electronic component and an interposer. The interposer is coupled to the electronic component. The interposer includes a signal transmission portion, a power regulating portion, and a data storage portion. The signal transmission portion is configured to transmit a first signal to the electronic component. The power regulating portion is configured to regulate a power transmitted to the electronic component. The data storage portion is coupled to the electronic component and configured to storage a second signal from the electronic component. The power regulating portion is closer to the signal transmission portion than the data storage portion is.

In some embodiments, an electronic device includes an electronic component and an interposer. The interposer is coupled to the electronic component. The interposer includes a signal transmission portion and a power transmission portion surrounding the signal transmission portion. The power transmission portion includes power transmission vias and a power regulating portion configured to modulate a power passing through the power transmission vias.

In some embodiments, an electronic device includes a first electronic component, a first interposer, and a second interposer. The first interposer is disposed over the first electronic component and configured to storage a signal from the first electronic component. The first interposer includes first signal transmission vias coupled to the first electronic component. The second interposer is disposed over the first electronic component and configured to regulate a power. The second interposer include second signal transmission vias coupled to the first electronic component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an example of an electronic device according to some embodiments of the present disclosure.

FIG. 2A is a partial enlarged view of an interposer according to some embodiments of the present disclosure.

FIG. 2B is a top view of the interposer of FIG. 1 according to some embodiments of the present disclosure.

FIG. 2C is a partial enlarged view of a capacitor according to some embodiments of the present disclosure.

FIG. 2D is a partial enlarged view of a memory device according to some embodiments of the present disclosure.

FIG. 3A is a top view of an interposer according to some embodiments of the present disclosure.

FIG. 3B is a partial enlarged view of the interposer as shown in FIG. 3A according to some embodiments of the present disclosure.

FIG. 4 illustrates a cross-sectional view of an example of an electronic device according to some embodiments of the present disclosure.

FIG. 5 illustrates a cross-sectional view of an example of an electronic device according to some embodiments of the present disclosure.

FIG. 6 illustrates a cross-sectional view of an example of an electronic device according to some embodiments of the present disclosure.

FIG. 7 illustrates a cross-sectional view of an example of an electronic device according to some embodiments of the present disclosure.

FIG. 8 illustrates a cross-sectional view of an example of an electronic device according to some embodiments of the present disclosure.

FIG. 9 illustrates a cross-sectional view of an example of an electronic device according to some embodiments of the present disclosure.

FIG. 10 illustrates a cross-sectional view of an example of an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

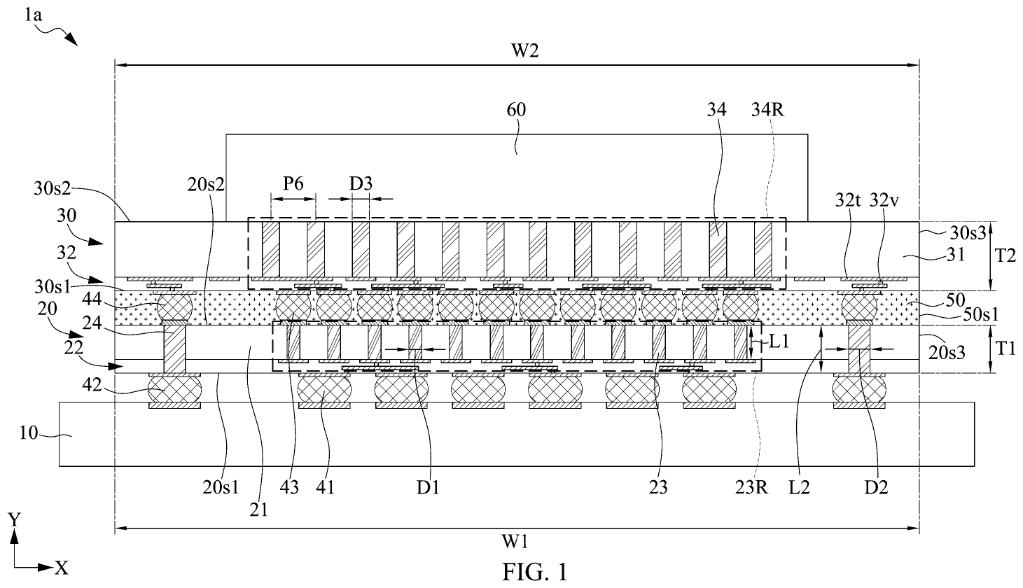

FIG. 1 illustrates a cross-sectional view of an example of an electronic device 1a according to some embodiments of the present disclosure. In some embodiments, the electronic device 1a may include a circuit structure 10, an interposer 20, an electronic component 30, an encapsulant 50, and a device 60.

The circuit structure 10 may be configured to support the interposer 20. In some embodiments, the circuit structure 10 may be configured to provide the interposer 20 with power (or a power signal). In some embodiments, the circuit structure 10 may be configured to transmit a signal(s) toward the interposer 20. In some embodiments, the circuit structure 10 may be configured to receive a signal (or non-power signal) from the interposer 20. The circuit structure 10 may be formed of, for example, a printed circuit board, such as a paper-based copper foil laminate, a composite copper foil laminate, or a polymer-impregnated glass-fiber-based copper foil laminate. The circuit structure 10 may include a redistribution layer (RDL) or traces for electrical connection between components. The circuit structure 10 can be replaced by other suitable carriers, such as a lead frame, substrate or core substrate. The circuit structure 10 may include conductive pads adjacent to or over the upper surface (not annotated) of the circuit structure 10.

The interposer 20 may be disposed on or over the circuit structure 10. In some embodiments, the interposer 20 may be configured to transmit power to the electronic component 30. In some embodiments, the interposer 20 may be configured to receive a signal from the electronic component 30. In some embodiments, the interposer 20 may include a carrier 21, a redistribution structure 22, conductive elements 23, and conductive elements 24. The interposer 20 may have a surface 20s1 (or lower surface) facing the circuit structure 10, a surface 20s2 (or upper surface) opposite to the surface 20s1, and a surface 20s3 (or lateral surface) extending between the surface 20s1 and surface 20s2.

The carrier 21 may include, for example but is not limited to, silicon (Si) or other suitable semi-conductive materials. Although not shown in FIG. 1, a redistribution structure may be formed on or over the carrier 21 to build a transmission path for transmitting power or a signal.

The redistribution structure 22 may be disposed on or under the carrier 21. The redistribution structure 22 may abut the surface 20s1. The redistribution structure 22 may include a plurality of traces and vias within one or more dielectric layers.

In some embodiments, the conductive element 23 (or signal transmission via) may be disposed at a central portion of the interposer 20. In some embodiments, the conductive element 23 may be configured to transceive a signal between the circuit structure 10 and the electronic component 30. In some embodiments, the conductive element 23 may include a conductive via or other suitable elements. In some embodiments, the conductive element 23 may penetrate the carrier 21. In some embodiments, the conductive element 23 may define a signal transmission portion 23R which is an imaginary region enclosing the conductive element 23.

In some embodiments, the conductive element 24 (or power transmission via) may be disposed at a peripheral portion of the interposer 20. In this disclosure, the peripheral portion of the interposer 20 may indicate a region closer to the surface 20s3 than the central portion is. In some embodiments, the conductive element 24 may be configured to transmit power to the electronic component 30. In some embodiments, the conductive element 24 may include a conductive via or other suitable elements. In some embodiments, the conductive element 24 may penetrate the carrier 21. In some embodiments, the conductive element 24 may penetrate the redistribution structure 22. For example, the conductive element 24 may penetrate the dielectric structure of the redistribution structure 22.

The conductive element 23 may have a length L1 along a direction (or vertical direction or the Y direction) from the surface 20s1 to the surface 20s2. The conductive element 24 may have a length L2 along a direction (or vertical direction) from the surface 20s1 to the surface 20s2. In some embodiments, the length L1 may be less than the length L2. The conductive element 23 may have a width DI along a direction (or horizontal direction or X direction) substantially orthogonal to the normal of the surface 20s1. The conductive element 24 may have a width D2 along a direction (or horizontal direction) substantially orthogonal to the normal of the surface 20s1. In some embodiments, the width D1 may be less than the width D2. Since the conductive element 24 has a relatively large dimension, the power loss may be reduced.

In some embodiments, the conductive elements 23 may be electrically connected to the circuit structure 10 by electrical connections 41. In some embodiments, the conductive elements 24 may be electrically connected to the circuit structure 10 by electrical connections 42. In some embodiments, the conductive elements 23 may be electrically connected to the electronic component 30 by electrical connections 43. In some embodiments, the conductive elements 24 may be electrically connected to the electronic component 30 by electrical connections 44. Each of the electrical connections 41, 42, 43, and 44 may include a reflowable material or a soldering material, such as gallium (Ga), indium (In), tin (Sn), bismuth (Bi), or other suitable materials.

The electronic component 30 may be disposed on or over the interposer 20. In some embodiments, the electronic component 30 may be configured to receive power from the interposer 20. In some embodiments, the electronic component 30 may be configured to generate, process, and/or transmit a signal. The electronic component 30 may have a surface 30s1 (or lower surface) facing the interposer 20, a surface 30s2 (or upper surface) opposite to the surface 30s1, and a surface 30s3 (or lateral surface) extending between the surface 30s1 and surface 30s2.

The electronic component 30 may include a semiconductor die or a chip, such as a logic die (e.g., system-on-a-chip (SoC), central processing unit (CPU), graphics processing unit (GPU), application processor (AP), microcontroller, etc.), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components.

The electronic component 30 may include a carrier 31, a redistribution structure 32 and conductive elements 34. The carrier 31 may include, for example but is not limited to, silicon (Si) or other suitable semi-conductive materials. Although not shown in FIG. 1, a redistribution structure may be formed on or over the carrier 31 to build a transmission path for transmitting a signal. The redistribution structure 32 may abut the surface 30s1. The redistribution structure 32 may include a plurality of traces 32t and vias 32v within one or more dielectric layers.

The conductive element 34 (or signal transmission via) may penetrate the carrier 31.

In some embodiments, the conductive element 34 may be configured to transceive a signal to interposer 20, the circuit structure 10, or the device 60. In some embodiments, the conductive element 34 may include a conductive via or other suitable elements. In some embodiments, the conductive element 34 may define a signal transmission portion 34R which is an imaginary region enclosing the conductive element 34. In some embodiments, the signal transmission portion 34R may vertically overlap the signal transmission portion 23R of the interposer 20. For example, the signal transmission portion 23R may be disposed under the signal transmission portion 34R. Accordingly, the signal transmission path between the electronic component 30 and the interposer 20 may be decreased. In some embodiments, the projection of the signal transmission portion 34R along a vertical direction (e.g., the Y direction) onto the surface 20s2 of the interposer 20 may be greater than the corresponding region, which is a part of the surface 20s2, of the signal transmission portion 23R. For example, in a cross-sectional view, the width of the projection, along the vertical direction, of the signal transmission portion 34R onto the surface 20s2 of the interposer 20 is greater than a width of the corresponding region of the signal transmission portion 23R. The conductive element 34 may have a width D3 along a direction (or horizontal direction) substantially orthogonal to the normal of the surface 30s1. In some embodiments, the width D1 may be less than the width D3. In some embodiments, the width D2 may be less than the width D3.

The interposer 20 may have a thickness T1 along a vertical direction (e.g., the Y direction). The electronic component 30 may have a thickness T2 along a vertical direction. In some embodiments, the thickness T2 may be greater than the thickness T1. The interposer 20 may have a width W1 along a horizontal direction. The electronic component 30 may have a width W2 along a horizontal direction. In some embodiments, the width W2 may be substantially equal to the width W1.

In some embodiments, the encapsulant 50 may be disposed between the circuit structure 10 and the electronic component 30. In some embodiments, the encapsulant 50 may encapsulate the electrical connections 43. In some embodiments, the encapsulant 50 may encapsulate the electrical connections 44. The encapsulant 50 may include a novolac-based resin, an epoxy-based resin, a silicone-based resin, or another suitable material. The encapsulant 50 can be applied using any of a number of molding techniques, such as compression molding, injection molding, or transfer molding. The encapsulant 50 may have a surface 50s1 (or a lateral surface). In some embodiments, the surface 50s1 may be substantially aligned with the surface 30s3. In some embodiments, the surface 50s1 may be substantially aligned with the surface 20s3.

In some embodiments, the device 60 (or electronic component) may be disposed on or over the surface 30s2 of the electronic component 30. The device 60 may be configured to receive a signal from the electronic component 30. In some embodiments, the device 60 may include a processing unit (CPU), graphics processing unit (GPU), application processor (AP), microcontroller, etc.), a memory die (e.g., static random access memory (SRAM) die, etc.), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components.

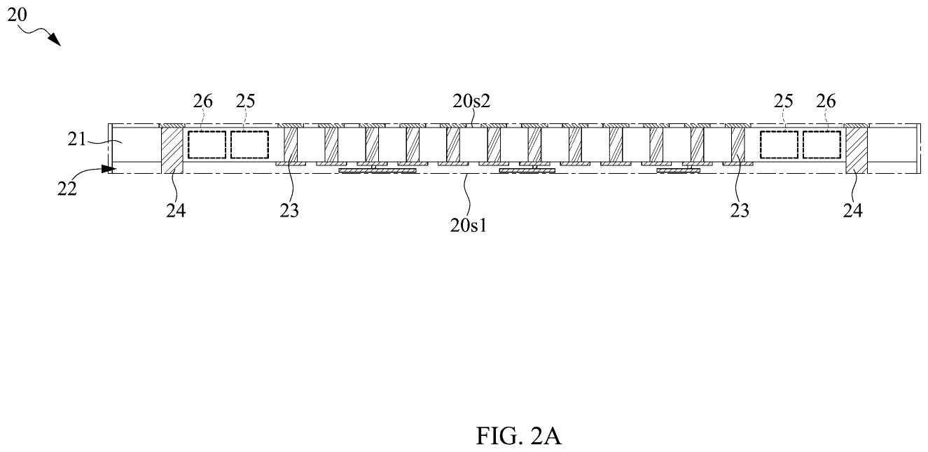

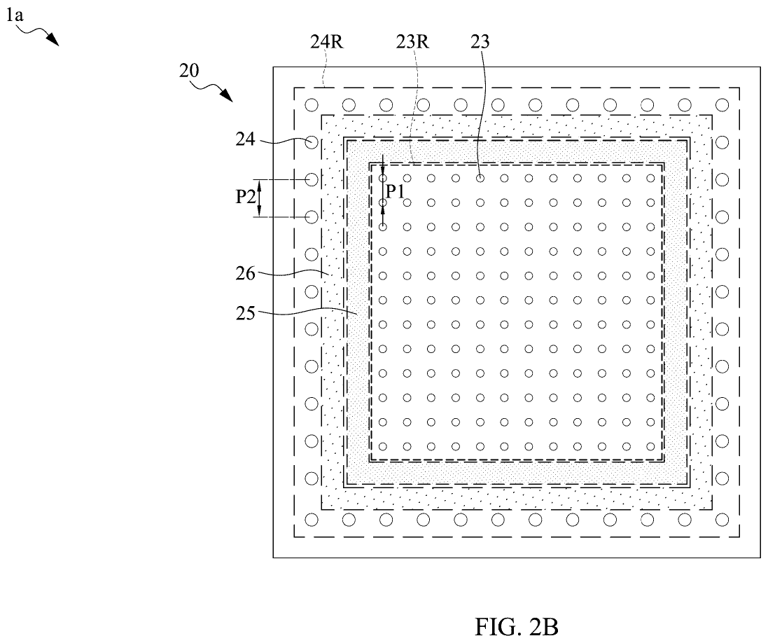

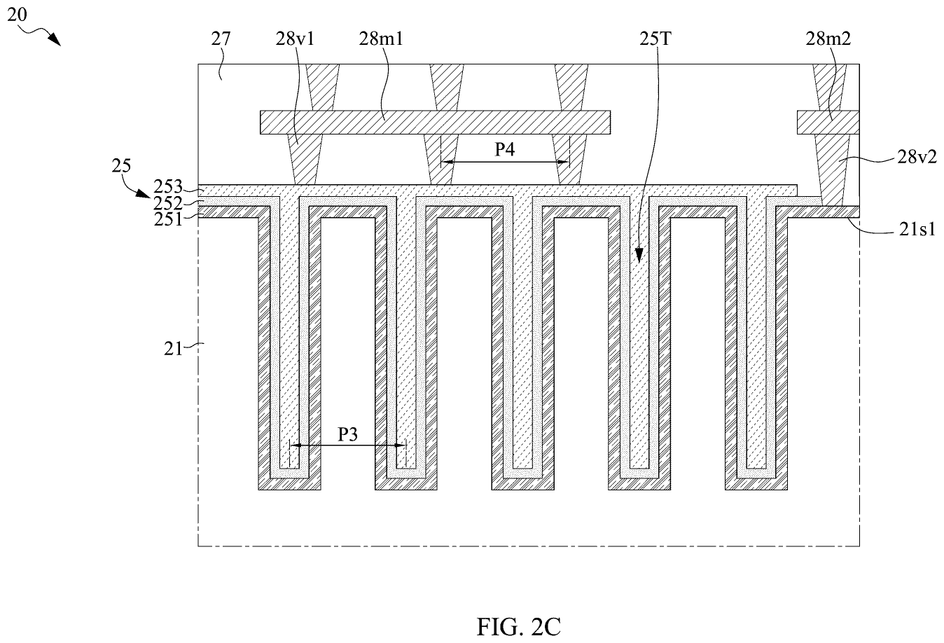

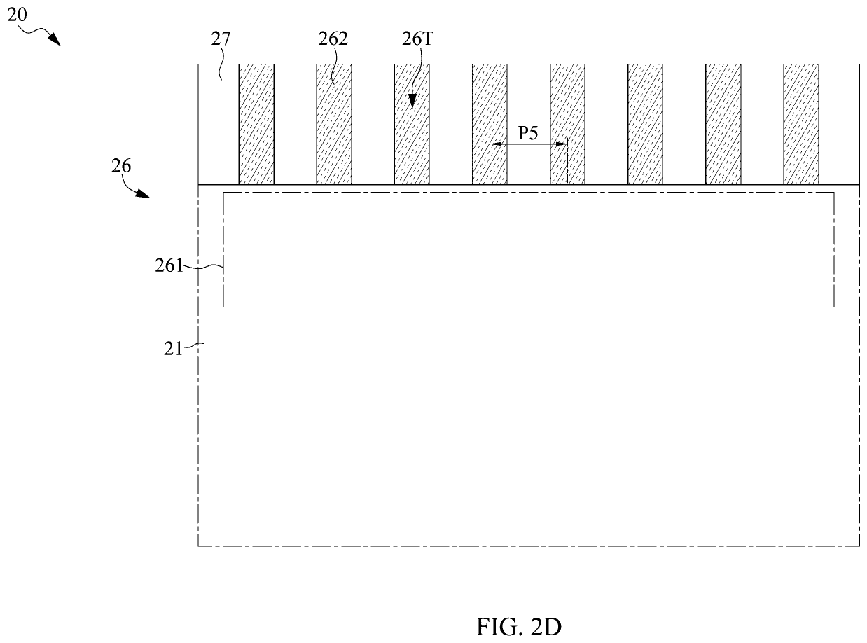

FIG. 2A is a partial enlarged view of the interposer 20 according to some embodiments of the present disclosure. In some embodiments, the interposer 20 may include a power regulating portion 25 and a data storage portion 26.

In some embodiments, the power regulating portion 25 may be closer to the conductive element 23 than to the conductive element 24. The power regulating portion 25 may be disposed between the conductive element 23 and the data storage portion 26. The power regulating portion 25 may include a passive component structure, such as a capacitor structure, an inductor structure, or other passive components. In some embodiments, the power regulating portion 25 may be configured to regulate the power, from the circuit structure 10, passing through the conductive element 24. In some embodiments, the power regulating portion 25 may be configured to regulate the signal passing through the conductive element 23. In some embodiments, the power regulating portion 25 may be configured to regulate the power transmitted to the electronic component 30.

Please refer to FIG. 2C, which is a partial enlarged view of the power regulating portion 25 according to some embodiments of the present disclosure. In some embodiments, the power regulating portion 25 may include a deep trench capacitor (DTC) structure. In some embodiments, the DTC structure of the power regulating portion 25 may define a plurality of trenches 25T. The trench 25T may be recessed from the surface 21s1 (e.g., upper surface) of the carrier 21. The power regulating portion 25 may include an electrode 251, a capacitor dielectric 252, and an electrode 253. Each of the electrode 251, capacitor dielectric 252, and electrode 253 may be disposed within the trenches 25T and on the upper surface of the carrier 21.

The interposer 20 may include a dielectric structure 27. The dielectric structure 27 may include a passivation layer(s) abutting the surface 20s2 of the interposer 20. The dielectric structure 27 may cover the power regulating portion 25. The dielectric structure 27 may include borophosphosilicate glass (BPSG), silicon oxide, silicon nitride, silicon oxynitride, undoped silicate glass (USG), or other suitable materials.

In some embodiments, the interposer 20 may include vias 28v1, vias 28v2, traces 28m1, and traces 28m2. The via 28v1 and trace 28m1 may be disposed within the dielectric structure 27. The via 28v1 and trace 28m1 may be electrically connected to the electrode 253. The via 28v2 and trace 28m2 may be disposed within the dielectric structure 27. The via 28v2 and trace 28m2 may be electrically connected to the electrode 251. The trace 28m1 may be configured to transmit a first voltage to the electrode 253, and the trace 28m2 may be configured to transmit a second voltage, different from the first voltage, to the electrode 251, thereby generating a capacitance between the electrodes 251 and 253. As a result, the power regulating portion 25 may be configured to regulate the power from the circuit structure 10 to the electronic component 30.

The trenches 25T may define a pitch P3. In some embodiments, the pitch P3 may be greater than the pitch P1. In some embodiments, the pitch P3 may be less than the pitch P2. The vias 28v1 (or vias 28v2) may define a pitch P4. In some embodiments, the pitch P4 may be greater than the pitch P1. In some embodiments, the pitch P4 may be less than the pitch P2.

Please refer back to FIG. 2A, in some embodiments, the data storage portion 26 may be closer to the conductive element 24 than to the conductive element 23. In some embodiments, the data storage portion 26 may be disposed between the conductive elements 23 and 24. The data storage portion 26 may include an active component, such as a memory structure. In some embodiments, the data storage portion 26 may include a dynamic random access memory (DRAM) structure. In some embodiments, the data storage portion 26 may be configured to storage a signal (or processed signal) from the electronic component 30. In some embodiments, the data storage portion 26 may be electrically coupled to the electronic component 30. In some embodiments, the data storage portion 26 may be electrically coupled to the conductive element 23.

Please refer to FIG. 2D, which is a partial enlarged view of the data storage portion 26 according to some embodiments of the present disclosure. The data storage portion 26 may include a memory unit which includes at least one transistor and capacitor. The data storage portion 26 may include an active region 261 and a plurality of capacitors 262. The active region 261 may be configured to switch the capacitor 262. In some embodiments, the active region 261 may include a transistor formed within and/or adjacent to the carrier 21.

The dielectric structure 27 may define a plurality of trenches 26T. The dielectric structure 27 may include a passivation layer(s) abutting the surface 20s2 of the interposer 20. Each of the capacitors 262 may be disposed within the trenches 26T. The capacitor 262 may include a first electrode, a second electrode, and a capacitor dielectric (not shown) between the first electrode and the second electrode.

The trenches 26T may define a pitch P5. In some embodiments, the pitch P5 may be greater than the pitch P3. In some embodiments, the pitch P5 may be greater than the pitch P4. In some embodiments, the pitch P5 may be less than the pitch P2.

Please refer to FIG. 2B, which is a top view of the interposer 20 according to some embodiments of the present disclosure. In some embodiments, the conductive elements 24 may define a power transmission portion 24R which is an imaginary region enclosing the conductive elements 24. In some embodiments, the power transmission portion 24R may surround the data storage portion 26. In some embodiments, the power transmission portion 24R may surround the power regulating portion 25. In some embodiments, the power transmission portion 24R may surround the signal transmission portion 23R.

The conductive elements 23 may define a pitch P1. The conductive elements 24 may define a pitch P2. In some embodiments, the pitch P2 may be greater than the pitch P1. In some embodiments, the pitch P1 may be less than a pitch P6, defined by the conductive elements 34, as shown in FIG. 1.

By arranging the power regulating portion 25 and data storage portion 26 as shown in FIG. 2A and FIG. 2B, the internal communication path may be decreased. For example, the power transmission path between the power regulating portion 25 and the conductive elements 24 may be decreased. Further, this arrangement effectively utilizes the space of the interposer 20, resulting in a relatively small dimension (e.g., width, surface area, or volume) of the interposer 20.

In a comparative example, an electronic component may integrate various circuits with different functions, such as an SOC die including DRAM circuits and passive circuits, leading to a large dimension that hinders the miniaturization of an electronic device. Additionally, signal transmitting pillars may be formed within an interposer, and power transmitting pillars may be formed within an encapsulant that encapsulates the interposer, resulting in lower yield in the bonding process among the electronic component, signal transmitting pillars, and power transmitting pillars due to pitch mismatch. In this embodiment, some of the active and/or passive components may be integrated within the unoccupied space of the interposer 20, reducing the overall device size. Furthermore, the conductive elements 23, conductive elements 24, power regulating portion 25 (or circuit), and data storage portion 26 (or circuit) are formed within the interposer 20, allowing for integrated manufacturing processes. This results in a similar dimension for the pitch, size of traces or other elements, and the pads of the conductive element 23, conductive element 24, power regulating portion 25, and data storage portion 26, effectively addressing the aforementioned issues.

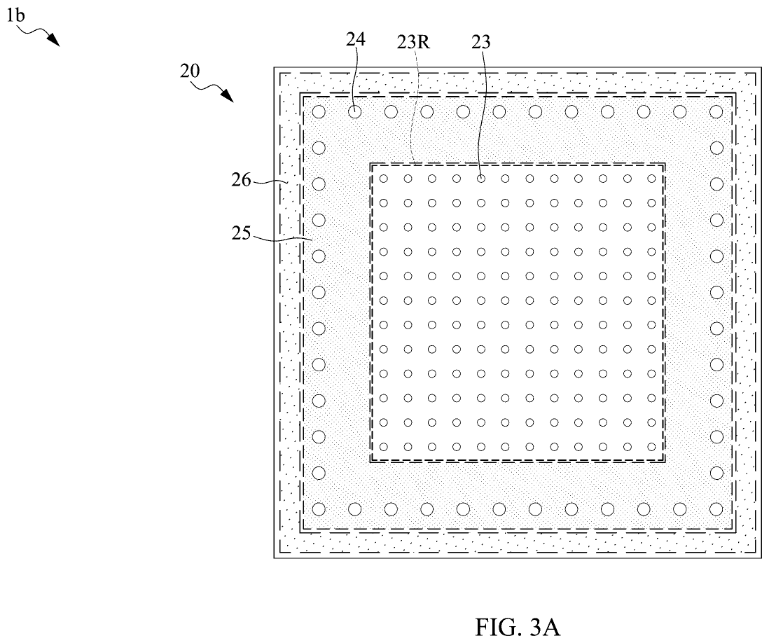

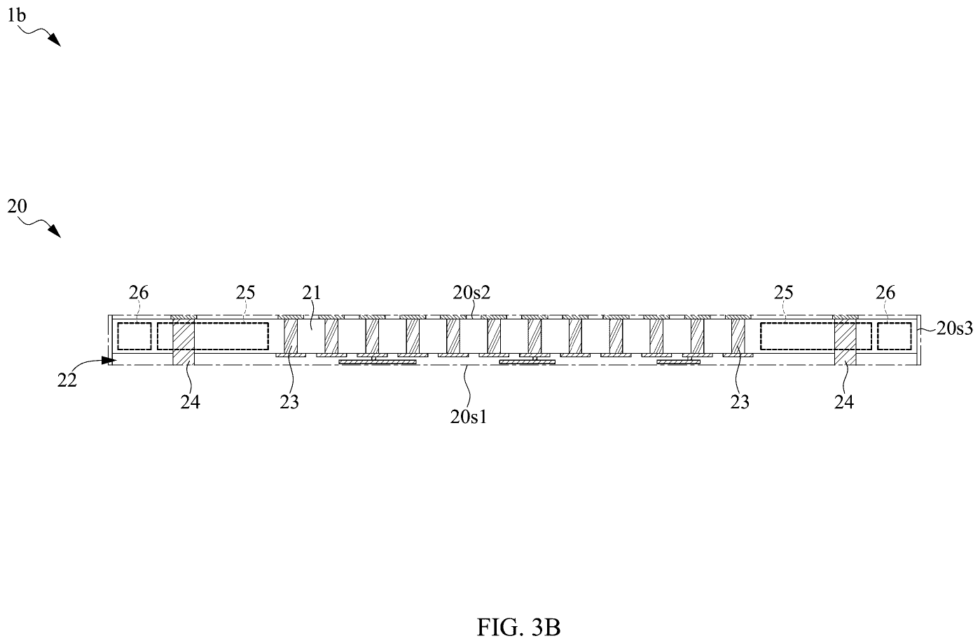

FIG. 3A and FIG. 3B illustrate an electronic device 1b according to some embodiments of the present disclosure. The electronic device 1b has a structure similar to that of the electronic device 1a, with differences outlined below.

In some embodiments, the conductive element 24 may be formed within a region (or portion) that accommodating the power regulating portion 25. In some embodiments, the conductive element 24 may be disposed between the data storage portion 26 and the conductive element 23. In some embodiments, the power transmitted by the conductive element 24 may be coupled to the power regulating portion 25. In this case, the power transmission path between the conductive element 24 and power regulating portion 25 may be reduced, thereby improving the power loss issue.

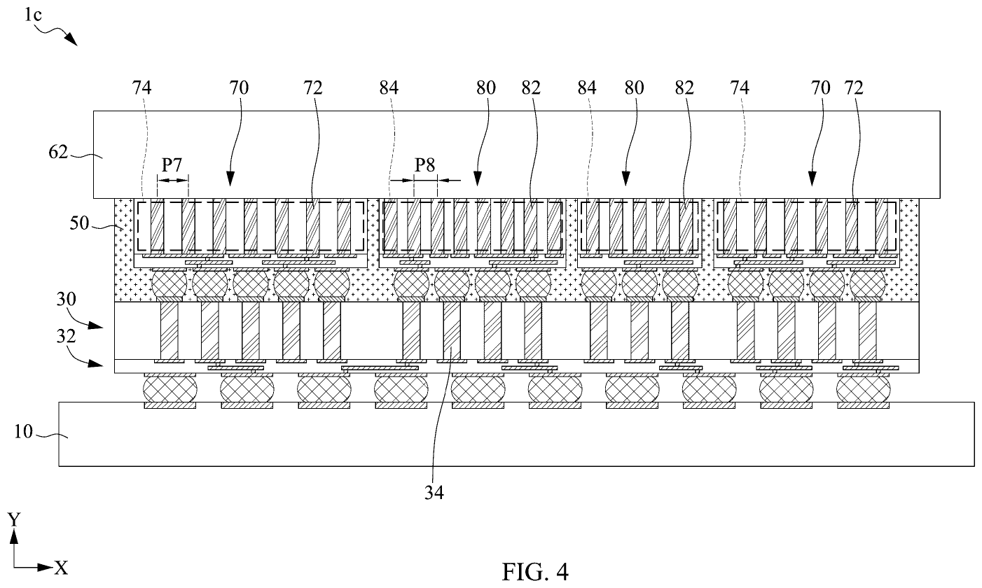

FIG. 4 illustrates a cross-sectional view of an example of an electronic device 1c according to some embodiments of the present disclosure. In some embodiments, the electronic devices 1c may include interposers 70, interposers 80, and a device 62.

In some embodiments, each of the interposers 70 (or memory interposer) may include conductive elements 72 (or signal transmission vias) and a circuit 74. In some embodiments, the interposer 70 may be configured to storage a signal from the electronic component 30 (or device 62). In some embodiments, the conductive element 72 may be configured to transmit a signal from the electronic component 30. In some embodiments, the circuit 74 may include an active component, such as a memory device (e.g., DRAM). In some embodiments, each of the interposers 70 may have different dimensions (e.g., width, surface area, and/or volume). In some embodiments, the pitch of the conductive elements 72 may be less than that of the conductive elements 34.

In some embodiments, each of the interposer 80 (or power regulating interposer) may include conductive elements 82 (or signal transmission vias) and a circuit 84. In some embodiments, the conductive element 82 may be configured to transmit a signal from the electronic component 30. In some embodiments, the interposer 80 may be configured to transmit power to the electronic component 30 (or device 62). In some embodiments, the conductive element 82 may be configured to transmit power coupled to the circuit 84 and/or the electronic component 30. In some embodiments, the circuit 84 may include a passive component (e.g., DTC). In some embodiments, each of the interposers 80 may have different dimensions (e.g., width, surface area, and/or volume). In some embodiments, the pitch of the conductive elements 82 may be less than that of the conductive elements 34.

In some embodiments, the interposers 70 may be surrounded by the interposers 80. For example, the interposer 80 may be disposed at a peripheral portion of the electronic component 30, and the interposer 70 may be disposed at a central portion of the electronic component 30. In some embodiments, a pitch P7 of the conductive elements 72 may be greater than a pitch P8 of the conductive elements.

In some embodiments, the electronic component 30 may be disposed on or over the circuit structure 10. In some embodiments, the electronic component 30 may be disposed between the circuit structure 10 and the interposer 70. In some embodiments, the electronic component 30 may be disposed between the circuit structure 10 and the interposer 80.

In some embodiments, the encapsulant 50 may be disposed on or over the electronic component 30. In some embodiments, the encapsulant 50 may encapsulate the interposers 70. In some embodiments, the encapsulant 50 may encapsulate the interposers 80. In some embodiments, an upper surface (not denoted) of the encapsulant 50 may be substantially aligned with an upper surface of the interposer 80 (or interposer 70).

The device 62 (or electronic component) may be disposed on or over the interposers 70 and the interposers 80. The device 62 may include a processing unit (CPU), graphics processing unit (GPU), application processor (AP), microcontroller, etc.), a memory die (e.g., static random access memory (SRAM) die, etc.), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components.

In this embodiment, some of the active components and/or passive components may be integrated within the unoccupied space of the interposer 70 and/or interposer 80, which can reduce the overall size of the electronic device 1c.

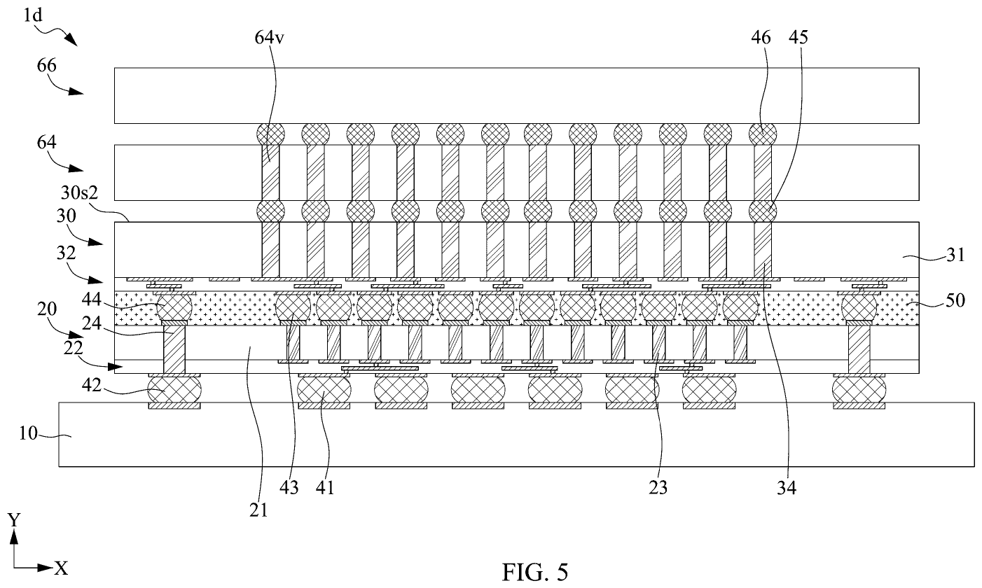

FIG. 5 illustrates a cross-sectional view of an example of an electronic device 1d according to some embodiments of the present disclosure. The electronic device 1d has a structure similar to that of the electronic device 1a, with differences outlined below.

In some embodiments, the electronic device 1d may include a device 64 and a device 66. The device 64 may be disposed on or over the electronic component 30. The device 66 may be disposed on or over the device 64. In some embodiments, each of the device 64 and device 66 may be disposed on or over the surface 30s2 of the electronic component 30. The device 64 (or device 66) may be configured to receive a signal from the electronic component 30. The device 64 (or device 66) may be configured to transmit a signal to the electronic component 30. In some embodiments, the device 64 (or device 66) may include a processing unit (CPU), graphics processing unit (GPU), application processor (AP), microcontroller, etc.), a memory die (e.g., static random access memory (SRAM) die, etc.), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active components.

In some embodiments, the device 64 may include conductive elements 64v. In some embodiments, each of the conductive elements 64v may include a conductive via or other suitable elements. In some embodiments, the conductive element 64v may be electrically connected to the electronic component 30 through electrical connections 45. In some embodiments, the conductive element 64v may be electrically connected to the device 66 through electrical connections 46.

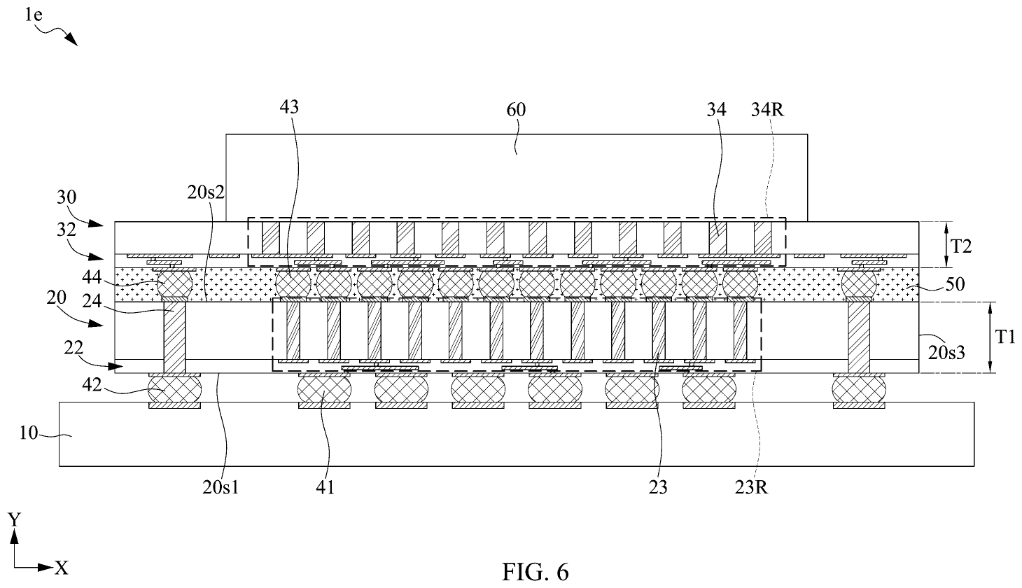

FIG. 6 illustrates a cross-sectional view of an example of an electronic device 1e according to some embodiments of the present disclosure. The electronic device 1e has a structure similar to that of the electronic device 1a, with a difference(s) outlined below.

In some embodiments, the thickness T2 of the electronic component 30 may be less than the thickness T1 of the interposer 20.

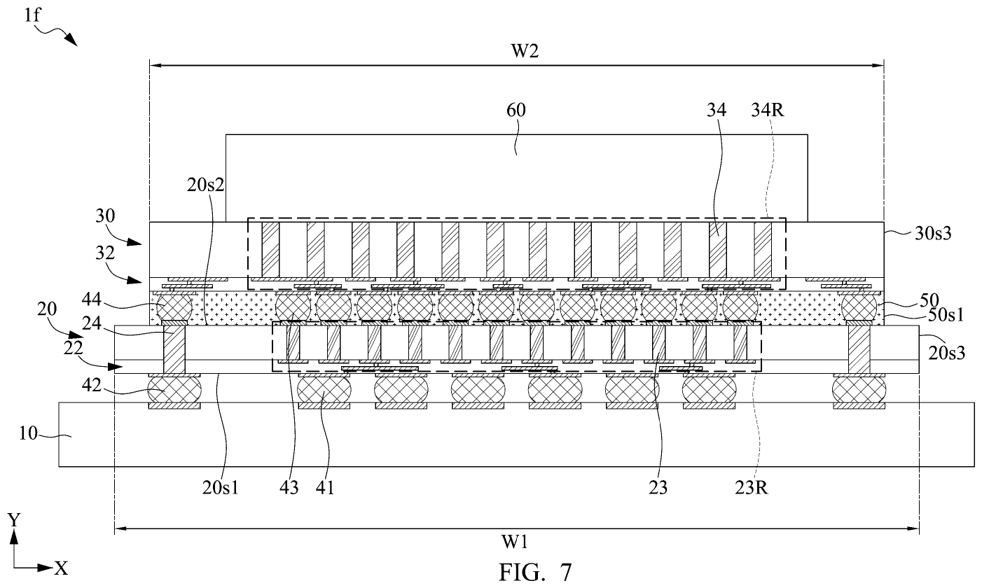

FIG. 7 illustrates a cross-sectional view of an example of an electronic device 1f according to some embodiments of the present disclosure. The electronic device If has a structure similar to that of the electronic device 1a, with differences outlined below.

In some embodiments, the width W2 of the electronic component 30 may be less than the width W1 of the interposer 20. In some embodiments, the surface 30s3 of the electronic component 30 may be substantially aligned with the surface 50s1 of the encapsulant 50. In some embodiments, the surface 20s3 of the interposer 20 may be misaligned with the surface 50s1 of the encapsulant 50.

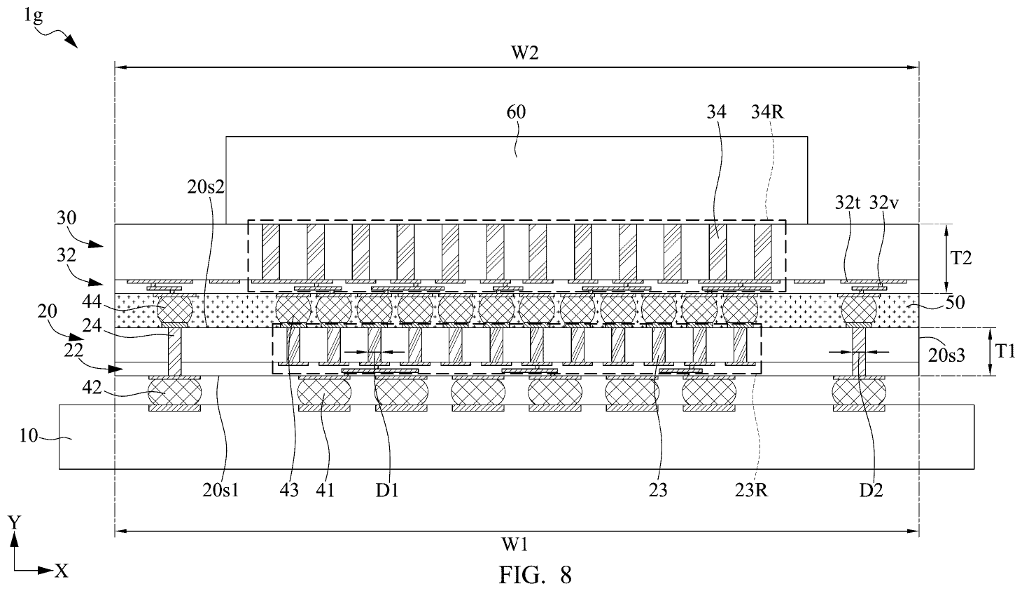

FIG. 8 illustrates a cross-sectional view of an example of an electronic device 1g according to some embodiments of the present disclosure. The electronic device 1g has a structure similar to that of the electronic device 1a, with a difference(s) outlined below.

In some embodiments, the width D1 of the conductive element 23 may be substantially equal to the width D2 of the conductive element 24.

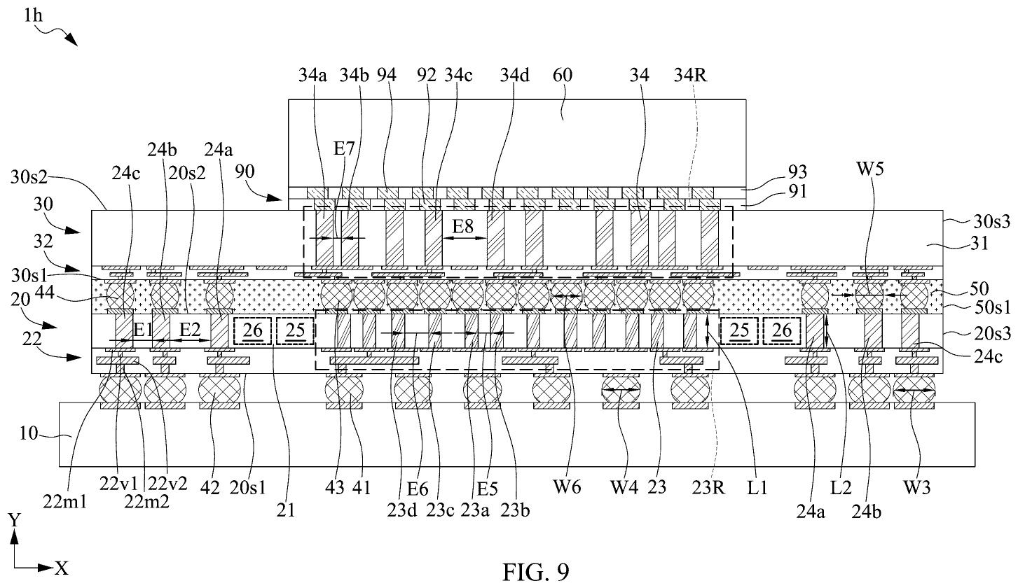

FIG. 9 illustrates a cross-sectional view of an example of an electronic device 1h according to some embodiments of the present disclosure. The electronic device 1h has a structure similar to that of the electronic device 1a, with a difference(s) outlined below.

The interposer 20 may include the power regulating portion 25 and the data storage portion 26. In some embodiments, the length L2 of the conductive element 23 is substantially equal to the length L1 of the conductive element 23. In some embodiments, the conductive element 24 may be electrically connected to the electrical connection 42 through the redistribution structure 22. In some embodiments, the redistribution structure 22 may include a via 22v1 and a via 22v2 under the via 22v1. In some embodiments, the dimension (e.g., the thickness, aperture, width, or the like) of the via 22v2 may be greater than that of the via 22v1. In some embodiments, the redistribution structure 22 may include a conductive trace 22m1 and a conductive trace 22m2 under the conductive trace 22m1. In some embodiments, the dimension (e.g., the thickness, diameter, line space/line width (L/S), or the like) of the conductive trace 22m2 may be greater than that of the conductive trace 22m 1. In some embodiments, the dimension (e.g., the width or the diameter) W3 of the electrical connection 42 may be greater than the dimension (e.g., the width or the diameter) W4 of the electrical connection 41. In some embodiments, the dimension (e.g., the width or the diameter) W5 of the electrical connection 44 may be less than the dimension (e.g., the width or the diameter) W6 of the electrical connection 43. In some embodiments, the conductive elements 24a, 24b, and 24c may have different distances therebetween. For example, the distance E2 between the conductive elements 24a and 24b may be greater than the distance E1 between the conductive elements 24b and 24c. In some embodiments, the electronic device 1h may include a hybrid-bond structure 90. The hybrid-bond structure 90 may be disposed between the electronic component 30 and the device 60. The hybrid-bond structure 90 may include a dielectric layer 91, conductive pads 92, a dielectric layer 93, and conductive pads 94. The dielectric layer 91 may be disposed on or over the electronic component 30. The dielectric layer 91 may include oxide or other suitable materials. The conductive pads 92 may be disposed within the dielectric layer 91. The dielectric layer 93 may be disposed on or over the dielectric layer 91. The dielectric layer 93 may include oxide or other suitable materials. The conductive pads 94 may be disposed within the dielectric layer 93 and electrically connected to the conductive pads 94. In some embodiments, the conductive pads 94 may be misaligned with the conductive pads 92. In some embodiments, two abutting conductive elements 23 may have different distances. For example, the conductive elements 23a and 23b have distance E5 therebetween, the conductive elements 23c and 23d have distance E6 therebetween, and the distance E6 may be greater than the distance E5. In some embodiments, two abutting conductive elements 34 may have different distances. For example, the conductive elements 34a and 34b have distance E7 therebetween, the conductive elements 34c and 34d have distance E8 therebetween, and the distance E8 may be greater than the distance E7.

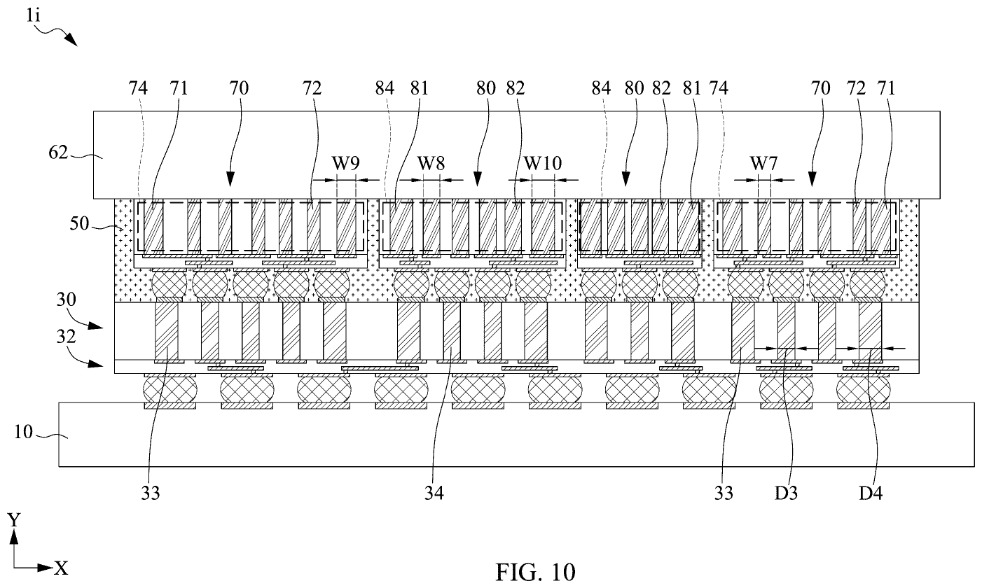

FIG. 10 illustrates a cross-sectional view of an example of an electronic device 1i according to some embodiments of the present disclosure. The electronic device 1i has a structure similar to that of the electronic device 1c, with a difference(s) outlined below.

The interposer 70 may have conductive elements 71 (or power transmission vias). The conductive element 71 may be configured to transmit power. The conductive element 71 may be closer to the side (or lateral surface) of the interposer 70 than the conductive element 72 is. The interposer 80 may have conductive elements 81 (or power transmission vias). The conductive element 81 may be configured to transmit power. The conductive element 81 may be closer to the side (or lateral surface) of the interposer 80 than the conductive element 82 is. The electronic component 30 may have conductive elements 33. The conductive element 33 may be configured to transmit power. The conductive element 33 may at least partially overlap the conductive element 71 or 81 along the Y direction.

The conductive element 72 may have a width W7 (or diameter). The conductive element 82 may have a width W8 (or diameter). In some embodiments, the width W7 may be greater than the width W8. The conductive element 71 may have a width W9 (or diameter). In some embodiments, the width W9 may be greater than the width W7. The conductive element 81 may have a width W10 (or diameter). In some embodiments, the width W10 may be greater than the width W8. The conductive element 33 may have a width D4 (or diameter). The width D4 may be greater than the width D3.

In some embodiments, the conductive elements 72 may have different distances therebetween. In some embodiments, the conductive elements 82 may have different distances therebetween. In some embodiments, the average distance (or average pitch) of abutting conductive elements 72 may be greater than the average distance (or average pitch) of abutting conductive elements 82. In some embodiments, the density of the conductive elements 72 may be less than the density of the conductive elements 82.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an electronic component; and
an interposer coupled to the electronic component, comprising:
a signal transmission portion configured to transmit a first signal to the electronic component;
a power regulating portion configured to regulate a power transmitted to the electronic component; and
a data storage portion coupled to the electronic component and configured to storage a second signal from the electronic component,
wherein the power regulating portion is closer to the signal transmission portion than the data storage portion is.

2. The electronic device of claim 1, wherein the data storage portion is closer to a lateral surface of the interposer than the power regulating portion is.

3. The electronic device of claim 2, wherein the electronic component comprises a plurality of first signal transmission vias, the signal transmission portion comprises a plurality of second signal transmission vias, and a pitch of the second signal transmission vias is less than a pitch of the first signal transmission vias.

4. The electronic device of claim 3, wherein a width of one of the second signal transmission vias is smaller than a width of one of the first signal transmission vias.

5. The electronic device of claim 1, wherein the interposer further comprises a plurality of power transmission vias, the signal transmission portion comprises a plurality of second signal transmission vias, and a pitch of the second signal transmission vias is less than a pitch of the power transmission vias.

6. The electronic device of claim 1, wherein the interposer further comprises a plurality of power transmission vias, the signal transmission portion comprises a plurality of second signal transmission vias, and a width of one of the second signal transmission vias is smaller than a width of one of the power transmission vias.

7. The electronic device of claim 1, wherein the power regulating portion comprises a capacitor structure defining trenches within the interposer, the signal transmission portion comprises a plurality of second signal transmission vias, and a pitch of the second signal transmission vias is less than a second pitch of the trenches of the capacitor structure.

8. The electronic device of claim 7, wherein the data storage portion comprises a plurality of memory units, and the pitch of the second signal transmission vias is less than a pitch of the memory units.

9. The electronic device of claim 8, wherein the pitch of the trenches of the capacitor structure is less than the pitch of the memory units.

10. The electronic device of claim 1, wherein the interposer further comprises a plurality of power transmission vias, the signal transmission portion comprises a plurality of second signal transmission vias, and a length of one of the power transmission vias is greater than a length of one of the second signal transmission vias.

11. An electronic device, comprising:
an electronic component; and
an interposer coupled to the electronic component, comprising:
a signal transmission portion; and
a power transmission portion surrounding the signal transmission portion,
wherein the power transmission portion comprises power transmission vias and a power regulating portion configured to modulate a power passing through the power transmission vias.

12. The electronic device of claim 11, further comprising:
a data storage portion, wherein the power transmission portion is disposed between the signal transmission portion and the data storage portion.

13. The electronic device of claim 11, wherein the electronic component comprises signal transmission vias at least partially penetrating the electronic component and electrically connected to the interposer through a redistribution structure.

14. The electronic device of claim 11, further comprising:
an additional electronic component stacked over the electronic component.

15. An electronic device, comprising:
a first electronic component; and
a first interposer disposed over the first electronic component and configured to storage a signal from the first electronic component, wherein the first interposer comprises first signal transmission vias coupled to the first electronic component; and
a second interposer disposed over the first electronic component and configured to regulate a power, wherein the second interposer comprises second signal transmission vias coupled to the first electronic component.

16. The electronic device of claim 15, further comprising:
a second electronic component disposed over the first interposer and the second interposer.

17. The electronic device of claim 15, wherein a pitch of the first signal transmission vias is greater than a pitch of the second signal transmission vias.

18. The electronic device of claim 16, wherein the first interposer further comprises first power transmission vias configured to transmit a power from the first electronic component to the second electronic component.

19. The electronic device of claim 16, wherein the second interposer further comprises second power transmission vias configured to transmit a power from the first electronic component to the second electronic component.

20. The electronic device of claim 15, wherein a width of the one of the first signal transmission vias is less than a width of the one of the second signal transmission vias.
